(19) United States
(12) Patent Application Publication
(10) Pub. No.: US 2013/0175238 A1
(43) Pub. Date: Jul. 11, 2013

(54) ETCHING SOLUTION AND METHOD OF MANUFACTURING PRINTED WIRING SUBSTRATE USING THE SAME

(71) Applicants: Dae Jo HONG, Gyunggi-do (KR); Chang Bo LEE, Gyunggi-do (KR); Cheol Ho CHOI, Gyunggi-do (KR); Chang Sup RYU, Gyunggi-do (KR); Sung Pyo HONG, Ulsan (KR); Jong Hoon JEON, Ulsan (KR); Akira HOSOMI, Tokyo (JP); Hiroshi TAKAMIYA, Tokyo (JP)

(72) Inventors: Dae Jo HONG, Gyunggi-do (KR); Chang Bo LEE, Gyunggi-do (KR); Cheol Ho CHOI, Gyunggi-do (KR); Chang Sup RYU, Gyunggi-do (KR); Sung Pyo HONG, Ulsan (KR); Jong Hoon JEON, Ulsan (KR); Akira HOSOMI, Tokyo (JP); Hiroshi TAKAMIYA, Tokyo (JP)

(73) Assignees: Samyoung Pure Chemicals Co., Ltd., Ulsan (KR); SAMSUNG ELECTRO-MECHANICS CO., LTD., Gyunggi-do (KR)

(21) Appl. No.: 13/474,335

(22) Filed: May 17, 2012

(30) Foreign Application Priority Data
Jan. 6, 2012 (KR) 1020120001828

(51) Int. Cl. C09K 13/06; H05K 3/00

(52) U.S. Cl. 216/13; 252/79.4

(57) ABSTRACT

This invention relates to an etching solution including hydrogen peroxide, sulfuric acid, chlorine ions, benzotriazole and pyrazole, and to a method of manufacturing a printed wiring substrate wherein the surface of the metal wiring of the printed wiring substrate is treated with an alkali solution, roughened using the etching solution and then subjected to anti-rust treatment, thus forming porous surface irregularities and micro anchors even with a small etching amount of the metal (Cu) to thereby obtain a high force of adhesion between the metal and an insulating material.

### CROSS-REFERENCE TO RELATED APPLICATION

This application claims the benefit of Korean Patent Application No. 10-2012-0001828, filed Jan. 6, 2012, entitled “Etching solution and method for preparing a print wiring substrate using the same,” which is hereby incorporated by reference in its entirety into this application.

### BACKGROUND OF THE INVENTION

1. Technical Field

The present invention relates to an etching solution and a method of manufacturing a printed wiring substrate using the same.

2. Description of the Related Art

In order to fabricate electronic products to be light, slim, short and small, printed circuit board (PCB) are an electronic part that is being manufactured in such a manner that a fine circuit line width of a substrate, via holes having a small diameter for interlayer connection, and very small bump pitches responsible for connection with a semiconductor chip are achieved. Particularly products having a circuit line width of about 10 μm or less are being developed these days.

In a conventional process of manufacturing a multilayered printed wiring substrate, an interlayer insulating resin is placed on a metal circuit formed on an insulating resin layer. Also to protect an outermost metal circuit layer, a solder resist (SR) or a coverlay may be disposed. In this case, after formation of the metal circuit, to enhance a force of adhesion of the metal circuit to an insulating resin (a prepreg, ABF (Ajinomoto Build up Film), or a solder resist) formed thereon, the surface of the metal circuit is remarkably roughened using an etching solution thus increasing physical (anchoring) effects. As such, an etching amount of 1 μm or more is required to obtain the desired surface roughness, and a circuit width margin of 2 μm or more is necessary to ensure the desired metal line width.

The desired circuit line width is conventionally obtained in such a manner that the line width which will be removed by etching is previously compensated for. For example, when the desired circuit line width is about 10 μm, the degree of compensation for the line width should be about 2 μm. Accordingly, upon forming a circuit having a line width of about 10 μm, the degree of compensation of about 2 μm is applied to form a total of about 12 μm, whereby the entire surface is etched with about 1 μm and then the line width is formed to about 10 μm. Meanwhile to obtain a predetermined force of adhesion (0.7 kgf/cm² or more) between the metal circuit and the insulating resin layer, the surface of the metal circuit is typically roughened using an etching solution, so that the surface roughness Ra (average roughness) of the metal circuit is 0.5 μm or more. This roughness may be obtained with the etching amount of about 1 μm or more.

Hence, the degree of compensation should correspond to the metal circuit width which will be reduced, and should be previously applied when forming a fine metal circuit. Particularly in a semi-additive process, when such a degree of compensation is applied, an area where a dry film resist, which functions as a plating resist, may be attached between metal wiring circuits becomes narrower, thus weakening the force of adhesion between the dry film resist and the metal seed layer to undesirably cause shorts, that is, the formation of connections between metal circuits, or making it impossible to form a uniform metal circuit line width. In this way, limitations are imposed on the formation of a fine metal circuit.

A metal wiring circuit of 10 μm or less is problematic because the metal circuit width may be partially reduced to about ½ to increase the roughness or there may occur shorts. An exemplary etching solution for roughening the surface of the metal circuit is an etching solution comprising an oxo acid such as sulfuric acid, a peroxide such as hydrogen peroxide, and an assistant component such as azole and chlorine, as disclosed in Korean Patent No. 10-0730519, and is also a micro etching solution in an aqueous solution phase composed mainly of an inorganic acid and an oxidant of copper and including azole and an etching inhibitor as assistant components (Japanese Unexamined Patent Publication No. 2000-282265).

Such conventional roughening agents (etching solutions) may etch the surface of the metal wiring with ones of μm, thus forming high roughness (large irregularities in a depth direction), and ensuring the adhesion between the metal wiring and the insulating resin layer thanks to physical anchoring effects.

However, conventional etching solutions are problematic because irregularities are formed on the surface of metal by etching in excessive amounts, and thus upon forming the circuit, a large degree of compensation (about 1 μm) for the line width is required, making it difficult to form a fine circuit of about 10 μm or less.

### SUMMARY OF THE INVENTION

Culminating in the present invention, intensive and thorough research with the aim of solving the problems occurring in the related art resulted in the finding that an etching solution composed essentially of benzotriazole and pyrazole may be used to perform etching with an etching amount of 0.5 μm or less so as to obtain fine metal (e.g. copper (Cu)) wiring of about 10 μm or less, and thus the surface roughness Ra of the etched metal wiring may be 0.5 μm or less, and the surface area after etching may be adjusted 2˜20 times compared to before etching.

Accordingly an aspect of the present invention is to provide an etching solution which may form porous surface irregularities and micro anchors with a small etching amount of Cu thus enhancing a high force of adhesion between Cu and an insulating material.

Another aspect of the present invention is to provide a method of manufacturing a printed wiring substrate, wherein the surface of a metal is finely roughened using the above etching solution so as to exhibit high adhesion between metal wiring and an insulating resin.

In order to accomplish the above aspects, the present invention provides an etching solution comprising hydrogen peroxide, sulfuric acid, chlorine ions, benzotriazole and pyrazole.

The etching solution of the present invention may comprise 1˜10 g/l of hydrogen peroxide, 5˜30 g/l of sulfuric acid, 0.0001˜0.005 g/l of chlorine ions, 0.1˜1 g/l of benzotriazole and 0.1˜0.5 g/l of pyrazole.

In the etching solution of the present invention, the benzotriazole may be at least one selected from among 1H-benzotriazole, 4-methylbenzotriazole and 5-methylbenzotrizole.

In the etching solution of the present invention, the pyrazole may be at least one selected from among 3,5-dimethylpyrazole, 2,3-dimethyl-1-phenyl-3-pyrazolin-5-one, 4-amino-2,3-dimethyl-1-phenyl-5-pyrazolone, 4-dimethylaminoantipyrine and 3-amino-5-hydroxypyrazole.

In the etching solution of the present invention, the molar ratio of hydrogen peroxide and sulfuric acid (hydrogen peroxide/sulfuric acid) may be 0.15˜1.0.

In addition, the present invention provides a method of manufacturing a printed wiring substrate using the above etching solution, comprising forming first metal wiring on a first insulating resin layer, and forming a second insulating resin layer on the first metal wiring; and forming second metal wiring on the second insulating resin layer, and forming a third insulating resin layer on the second metal wiring, wherein the surface of each of the first metal wiring and the second metal wiring is treated with an alkali solution, roughened using an etching solution comprising hydrogen peroxide, sulfuric acid, chlorine ions, benzotriazole and pyrazole, and then subjected to anti-rust treatment using an anti-rust agent.

In the method of the present invention, the alkali solution may be an aqueous solution at pH of 9 or more.

In the method of the present invention, the etching solution may comprise 1˜10 g/l of hydrogen peroxide, 5˜30 g/l of sulfuric acid, 0.0001˜0.005 g/l of chlorine ions, 0.1˜1 g/l of benzotriazole and 0.1˜0.5 g/l of pyrazole.

In the method of the present invention, the anti-rust agent may be an aqueous solution containing a silane compound or an amine compound.

In the method of the present invention, an etching amount of each of the first metal wiring and the second metal wiring may be 0.5 μm or less, and a surface roughness Ra thereof may be 0.5 μm or less.

In the method of the present invention, the surface area of each of the first metal wiring and the second metal wiring after etching may be 2˜20 times the surface area of the metal wiring before etching.

In the method of the present invention, the benzotriazole may be at least one selected from among 1H-benzotriazole, 4-methylbenzotriazole and 5-methylbenzotrizole.

In the method of the present invention, the pyrazole may be at least one selected from among 3,5-dimethylpyrazole, 2,3-dimethyl-1-phenyl-3-pyrazolin-5-one, 4-amino-2,3-dimethyl-1-phenyl-5-pyrazolone, 4-dimethylaminoantipyrine and 3-amino-5-hydroxypyrazole.

In the method of the present invention, the molar ratio of hydrogen peroxide and sulfuric acid (hydrogen peroxide/sulfuric acid) may be 0.15˜1.0.

In the method of the present invention, the temperature of the etching solution may be 20˜40° C.

### BRIEF DESCRIPTION OF THE DRAWINGS

FIGS. 1 to 11 are field emission-scanning electron microscope (FE-SEM) images showing the surface morphology of Cu foil at 10,000, 30,000 and 100,000 magnification after etching treatment in Examples 1 to 11 according to the present invention; and

FIGS. 12 to 24 are FE-SEM images showing the surface morphology of Cu foil at 10,000, 30,000 and 100,000 magnification after etching treatment in Comparative Examples 1 to 13 according to the present invention.

### DESCRIPTION OF SPECIFIC EMBODIMENTS

The features and advantages of the present invention will be more clearly understood from the following detailed description and embodiments.

Furthermore, the terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept implied by the term to best describe the method he or she knows for carrying out the invention.

Below is a detailed description of embodiments of the present invention with reference to the appended drawings.

According to the present invention, an etching solution includes hydrogen peroxide, sulfuric acid, chlorine ions, benzotriazole and pyrazole. In particular, the etching solution according to the present invention essentially includes benzotriazole and pyrazole.

In the present invention, the concentration of hydrogen peroxide may be 1˜10 g/l, and particularly 1˜8 g/l, and more particularly 2˜7 g/l. If the concentration thereof is less than 1 g/l, oxidation effects may become insufficient. In contrast, if the concentration thereof exceeds 10 g/l, the predetermined amount or more of oxidation effects cannot be obtained thus nullifying the profitability.

The concentration of sulfuric acid may fall in the range of 5˜30 g/l, particularly 10˜30 g/l, and more particularly 20˜30 g/l. If the concentration thereof is less than 5 g/l, the melting rate of metal (Cu) may not be sufficient. In contrast, if the concentration thereof exceeds 30 g/l, the melting rate may be mostly unchanged thus nullifying the profitability.

The molar ratio of hydrogen peroxide and sulfuric acid (hydrogen peroxide/sulfuric acid) may be 0.15˜1.0, particularly 0.3˜0.8, and more particularly 0.4˜0.7. If the molar ratio is less than 0.15 and exceeds 1.0, uniform roughness cannot be formed on the metal wiring after etching.

Also, the concentration of chlorine ions may be 0.0001˜0.005 g/l, particularly 0.0001˜0.004 g/l, and more particularly 0.00015 g/l˜0.0035 g/l. If the concentration thereof is less than 0.0001 g/l, etching effects may be insufficient. In contrast, if the concentration thereof exceeds 0.005 g/l, etching effects cannot be obtained any more, thus nullifying the profitability. The chlorine ions may be obtained from hydrochloric acid, sodium chloride, potassium chloride, etc.

The benzotriazole may be at least one selected from among 1H-benzotriazole, 4-methylbenzotriazole and 5-methylbenzotriazole, and the concentration thereof may be 0.1˜1 g/l, particularly 0.1˜0.8 g/l, and more particularly 0.2˜0.6 g/l. If the concentration thereof is less than 0.1 g/l, effects by the addition thereof may decrease. In contrast, if the concentration thereof exceeds 1 g/l, the roughness may increase excessively.

In the present invention, the pyrazole may be at least one selected from among 3,5-dimethylpyrazole, 2,3-dimethyl-1-phenyl-3-pyrazolin-5-one, 4-amino-2,3-dimethyl-1-phenyl-5-pyrazolone, 4-dimethylaminoantipyrine and 3-amino-5-hydroxypyrazole. The amount thereof may be 0.1˜0.5 g/l. More particularly the pyrazole may include 3,5-dimethylpyrazole, 2,3-dimethyl-1-phenyl-3-pyrazolin-5-one, 4-amino-2,3-dimethyl-1-phenyl-5-pyrazolone, and/or 4-dimethylaminoantipyrine. The concentration of the pyrazole may be 0.1˜0.5 g/l, particularly 0.1˜0.4 g/l, and more particularly 0.15˜0.35 g/l. If the concentration thereof is less than 0.1 g/l, there is almost no effect upon its addition. In contrast if the concentration thereof exceeds 0.5 g/l, fine and uniform roughness cannot be obtained after etching.

As mentioned above, the etching solution according to the present invention essentially contains two kinds of azole compounds including benzotriazole and pyrazole in the above concentration ranges, and thereby the surface of metal may be finely roughened with an etching amount of about 0.5 μm or less to form a fine surface roughness Ra of abut 0.5 μm or less. In the present invention, because the benzotriazole functions to form a relatively high roughness on metal wiring and the pyrazole acts to form a lower roughness, the combination of benzotriazole, pyrazole and chlorine ions results in a formation of uniform and dense roughness.

The temperature of the etching solution is 20˜40° C., and particularly 20˜30° C. Even if the temperature thereof is lower than 20° C., the etching solution may be used but the etching rate may decrease and is thus inefficient. As the temperature thereof increases, the stability of hydrogen peroxide may deteriorate and the surface of the metal is not uniformly roughened.

Such an etching solution is used in a method of manufacturing a printed wiring substrate. This method comprises forming first metal wiring on a first insulating resin layer, forming a second insulating resin layer on the first metal wiring, forming second metal wiring on the second insulating resin layer, and forming a third insulating resin layer on the second metal wiring, thus obtaining the printed wiring substrate according to the present invention. As such, a printed wiring substrate that boasts of high adhesion between the metal wiring and the insulating resin may be manufactured by a first process of treating the surface of each of the first metal wiring and the second metal wiring with an alkali solution, a second process of etching the surface of metal with an etching amount of about 0.5 μm or less using an etching solution comprising hydrogen peroxide, sulfuric acid, chlorine ions, benzotriazole and pyrazole so that the surface roughness Ra of the metal wiring is about 0.5 μm or less, and a third process of subjecting the surface of metal to anti-rust treatment using an anti-rust agent.

The alkali solution used in the first process of the present invention is an aqueous alkali solution at pH of 9 or more, particularly 10 or more. If the pH is less than 9, pretreatment effects are low, and the surface uniformity of the metal wiring may decrease after the etching done in the second process. Furthermore, the excessive use of the aqueous alkali solution negates profitability. The temperature of the aqueous alkali solution is not particularly limited, but may fall in the range from room temperature (typically about 25° C.) to 50° C., and particularly from room temperature to 35° C. If the temperature thereof is high, profitability is negated.

The alkali may include an inorganic alkali, and an organic alkali. Examples of the inorganic alkali include sodium hydroxide, potassium hydroxide, aluminum hydroxide, lithium hydroxide, etc., and sodium hydroxide is particularly useful in terms of profitability and handleability.

Examples of the organic alkali include quaternary ammonium hydroxides such as tetramethyl ammonium hydroxide, trimethylethyl ammonium hydroxide, dimethyldiethyl ammonium hydroxide and trimethyl(2-hydroxiethyl)ammonium hydroxide.

The aqueous alkali solution may further include a surfactant used in the art as a typical surface treatment agent, and there is no adverse effect even when such a surfactant is added.

The etching solution used in the second process is an aqueous solution containing hydrogen peroxide, sulfuric acid, chlorine ions, benzotriazole and pyrazole as mentioned above.

After the second process is performed using the above etching solution, the oxide film formed upon etching may be removed using an acidic aqueous solution. The acidic aqueous solution may include an inorganic acid such as sulfuric acid, hydrochloric acid, phosphoric acid, etc., and an organic acid such as citric acid, malic acid, oxalic acid, etc. Among these, hydrochloric acid is particularly useful.

The anti-rust agent used in the third process of the present invention is an aqueous solution of a silane compound or an amine compound. The aqueous silane compound may include 3-aminopropyl trimethoxysilane, 3-aminopropyl triethoxysilane, N-2-(aminoethyl)-3-aminopropyl trimethoxysilane, N-2-(aminoethyl)-3-aminopropyl triethoxysilane, and N-2-(aminoethyl)-3-aminopropyl methyl dimethoxysilane. The concentration of the silane compound may be 1˜50 g/l, particularly 3˜40 g/l, and more particularly 0.3˜40 g/l.

The aqueous amine compound may include at least one selected from among 2-aminopyridine, 2-aminoquinoline, 2-aminopyrimidine, 6-aminopyrimidine, 2-aminopyrazine, 2-aminoquinazolin, 4-aminoquinazolin, 2-aminoquinoxaline, 8-aminopurine, 2-aminobenzimidazole, aminotriazine, aminotriazole, aminotetrazole and substituted derivatives thereof. Particularly useful are aminotetrazole and/or derivatives thereof, and aminotriazole and/or derivatives thereof. The concentration of the amine compound may be 0.1˜100 g/l, and particularly 0.5˜50 g/l.

In the second process, the etching amount may be 0.5 μm or less, particularly 0.4 μm or less, and more particularly 0.3 μm or less. The surface roughness Ra of the metal wiring may be 0.5 μm or less because of transfer loss, and particularly 0.3 μm or less. The adhesive strength may be 0.7 kgf/cm² or more, particularly 0.8 kgf/cm² or more, and more particularly 1.0 kgf/cm² or more. Only when the surface area of the metal wiring after etching is 2˜20 times the surface area before etching, the etched metal may function as a micro anchor creating a high force of adhesion between the metal and the insulating material.

The treatment of the metal wiring using a surface treatment solution in the present invention is not particularly limited, but immersion, spraying, etc., may be appropriately adopted. The treatment time is appropriately determined by the thickness of the melted metal.

Forming the metal wiring on the insulating resin layer may be typically performed using a subtractive process or a semi-additive process.

The subtractive process is carried out by forming an etching resist layer on the surface of metal, performing photo-exposure and development thus forming a resist pattern, removing the unnecessary metal by etching, and then stripping the resist, thus forming the wiring.

The semi-additive process is conducted by forming a metal layer (a seed layer) on an insulating resin, forming a plating resist layer on the surface of the metal layer, performing photo-exposure and development thus forming a resist pattern, followed by performing Cu electroplating, stripping the resist, and removing the unnecessary seed layer by etching, thus forming the wiring.

In the present invention, forming the metal wiring may be carried out by using either the subtractive process or the semi-additive process.

The following examples which are set forth to illustrate but are not to be construed as limiting the present invention may provide a better understanding of the present invention.

### Examples 1 and 2

The amounts of hydrogen peroxide and sulfuric acid were set to 0.5 wt % and 1.5 wt %, and the additives were used in the concentrations shown in Table 1 below thus preparing etching solutions (the balance component being water), which were then used to etch an electrodeposited Cu foil (3 cm×5 cm) with 0.3 μm. The etching treatment was performed using a spray having a full-cone nozzle, and the temperature thereof was set to about 30° C.

### Comparative Examples 1 to 3

These examples were performed in the same manner as in Example 1 and the same evaluation method was applied, although the exception thereto was that the concentrations of the additives were changed.

### Comparative Examples 4 and 5

An electrodeposited Cu foil (3 cm×5 cm) was etched with 0.6 μm and 1.1 μm using a CZ8301 etching solution available from MEC. The etching treatment was performed using a spray having a full-cone nozzle, and the temperature thereof was set to about 30° C.

In Table 1 below, the etching amount was calculated from the weight difference before and after treatment of the electrodeposited Cu foil, and the calculation thereof is represented by Equation 1 below.

Etching amount (μm)=[weight (g) before treatment−weight (g) after treatment]/substrate area (m²)/Cu gravity (8.92) [Equation 1]

The surface roughness of the Cu foil was represented by Ra obtained via five measurements using a non-contact type microscope NV-2000 available from Nano System and the standard deviation (SD). The surface morphology of the Cu foil was observed at 10,000, 30,000 and 100,000 magnification using FE-SEM S-4800 available from Hitachi. The etching uniformity was evaluated by O when being totally uniform, ◯ when being partially non-uniform, and × when being non-uniform, and the surface morphologies in the etching amount of 0.3 μm were visually compared using FE-SEM images.

For reference, the abbreviations in Tables 1 to 3 below are as follows:

5 MBTZ: 5-methyl benzotriazole

1HBTA: 1H-benzotriazole

1HP: 1H-pyrazole

AN: antipyrine

4AA: 4-aminoantipyrine

4DAA: 4-dimethyl aminoantipyrine

3A5HP: 3-amino-5-hydroxy pyrazole

35DMP: 3,5-dimethylpyrazole

TABLE 1

| | | C. Ex. 1 | C. Ex. 2 | C. Ex. 3 | Ex. 1 | Ex. 2 | C. Ex. 4 | C. Ex. 5 |
|---|---|---|---|---|---|---|---|---|
| Benzotriazole (ppm) | | 5MBTZ | — | — | 5MBTZ | 1HBTA | — | — |
| | | (500 ppm) | | | (500 ppm) | (1000 ppm) | | |
| Pyrazole (ppm) | | — | 35DMP | — | 35DMP | 35DMP | — | — |
| | | | (250 ppm) | | (250 ppm) | (500 ppm) | | |
| Etching amount (μm) | | 0.3 | 0.3 | 0.3 | 0.3 | 0.3 | 0.6 | 1.1 |
| Roughness | Ra (nm) | 269 | 220 | 242 | 237 | 294 | 382 | 439 |
| | SD | 23.3 | 35.0 | 23.0 | 11.1 | 2.0 | 11.0 | 11.0 |

| | | | | | | | |
|---|---|---|---|---|---|---|---|
| Etching Uniformity | ◯ | X | X | ⊚ | ⊚ | ⊚ | ⊚ |

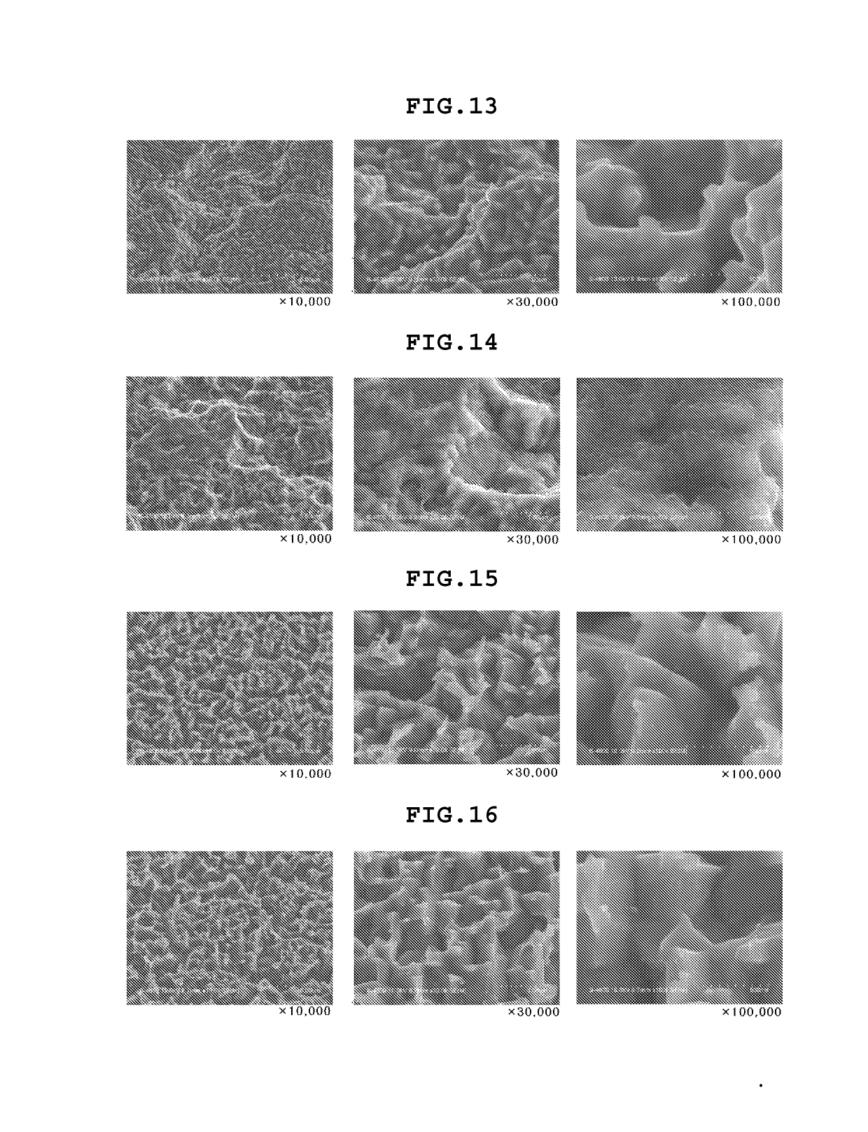

As is apparent from Table 1, the use of the compositions of Comparative Examples 1 and 2 respectively containing benzotriazole and pyrazole resulted in poor etching uniformity (FIGS. 13˜14), whereas the compositions of Examples 1 and 2 containing the mixture of benzotriazole and pyrazole exhibited good uniformity (FIGS. 1˜2), and had the lower surface roughness Ra compared to Comparative Examples 4 and 5 (using the commercially available etching solution) showing the surface in the form of small protrusions at high magnification as seen in FIGS. 15˜16.

### Example 3

The amounts of hydrogen peroxide and sulfuric acid were set to 0.5 wt % and 1.5 wt %, and the additives were used in the concentrations shown in Table 2 below thus preparing etching solutions (the balance component being water), which were then used to etch an electrodeposited Cu foil (3 cm×5 cm) with 0.3 μm. The etching treatment was performed using a spray having a full-cone nozzle, and the temperature thereof was set to about 30° C. The surface morphologies in the etching amount of 0.3 μm were visually compared using FE-SEM images (FIG. 3).

### Comparative Examples 6 to 13

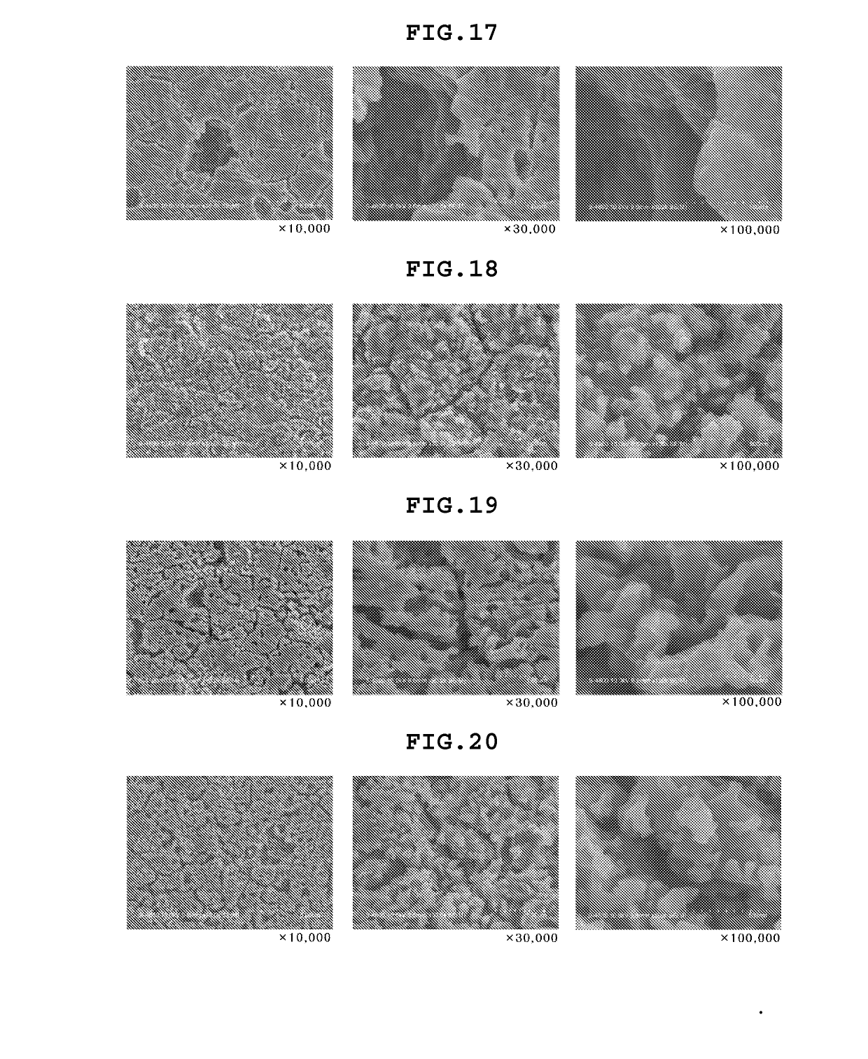

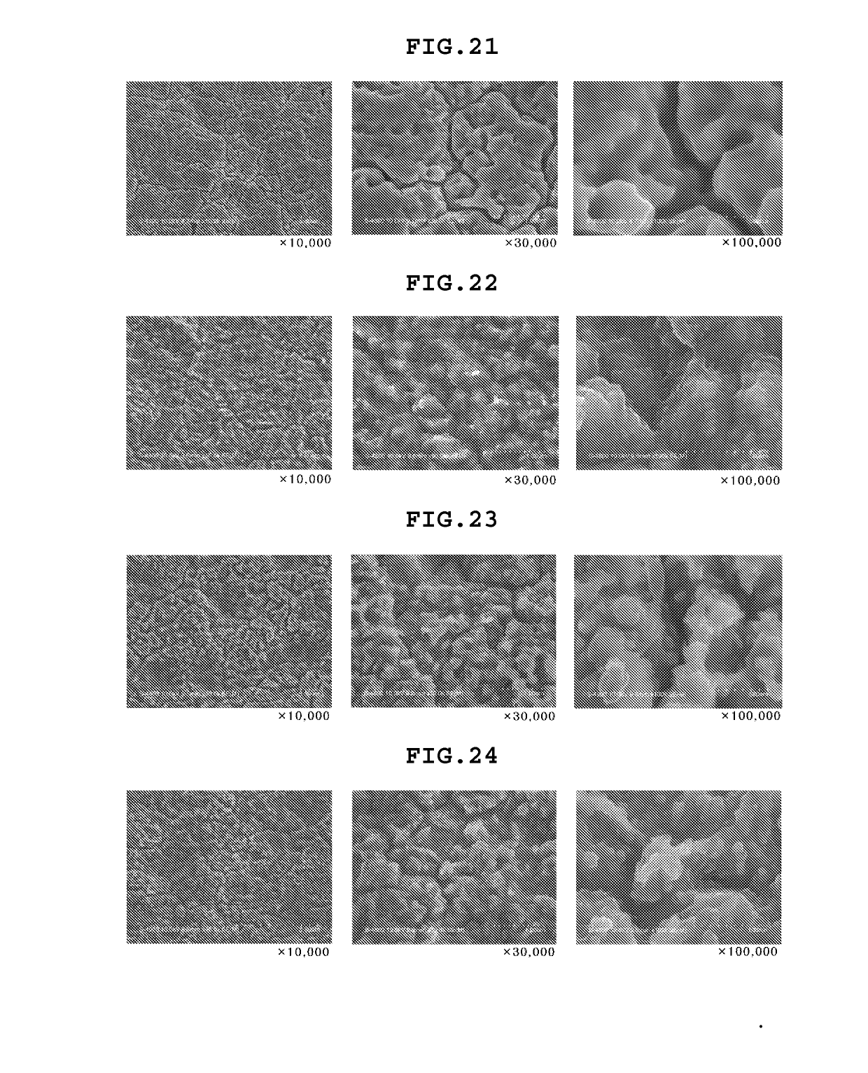

The concentration of benzotriazole (100˜1500 ppm) and the concentration of pyrazole (50˜500 ppm) of Example 3 were changed and thus the surface morphologies were compared. The results are shown in Table 2 below. The surface morphologies in the etching amount of 0.3 μm were visually compared using FE-SEM images (FIGS. 17˜24).

TABLE 2

| | | | | Roughness | | |
|---|---|---|---|---|---|---|
| | | | Etching | Ra | | Etching |
| | Benzotrizole (ppm) | Pyrazole (ppm) | amount (μm) | (nm) | SD | Uniformity |
| C. Ex. 6 | 5MBTZ | 35DMP | 0.3 | 215 | 44.4 | X |
| | (50 ppm: less than | (250 ppm) | | | | |
| | the range) | | | | | |
| C. Ex. 7 | 5MBTZ | 35DMP | 0.3 | 290 | 12.7 | ◯ |
| | (1600 ppm: more than | (250 ppm) | | | | |
| | the range) | | | | | |
| C. Ex. 8 | 5MBTZ | 35DMP | 0.3 | 300 | 7.5 | ◯ |
| | (500 ppm) | (10 ppm: less | | | | |
| | | than the range) | | | | |
| C. Ex. 9 | 5MBTZ | 35DMP | 0.3 | 258 | 5.0 | ◯ |
| | (500 ppm) | (600 ppm: more | | | | |
| | | than the range) | | | | |
| C. Ex. 10 | 1HBTA | 35DMP | 0.3 | 236 | 33.6 | X |
| | (50 ppm: less than | (400 ppm) | | | | |
| | the range) | | | | | |
| C. Ex. 11 | 1HBTA | 35DMP | 0.3 | 305 | 28.0 | X |
| | (1600 ppm: more than | (400 ppm) | | | | |
| | the range) | | | | | |
| C. Ex. 12 | 1HBTA | 35DMP | 0.3 | 297 | 10.5 | ◯ |
| | (800 ppm) | (10 ppm: less | | | | |
| | | than the range) | | | | |
| C. Ex. 13 | 1HBTA | 35DMP | 0.3 | 302 | 11.5 | X |
| | (800 ppm) | (600 ppm: more | | | | |
| | | than the range) | | | | |
| Ex. 1 | 5MBTZ | 35DMP | 0.3 | 237 | 11.1 | ⊚ |
| | (500 ppm: normal) | (250 ppm: normal) | | | | |
| Ex. 3 | 1HBTA | 35DMP | 0.3 | 243 | 2.7 | ⊚ |
| | (800 ppm: normal) | (400 ppm: normal) | | | | |

### Examples 4 to 11

The amounts of hydrogen peroxide and sulfuric acid were set to 0.5 wt % and 1.5 wt %, and the additives including two kinds of benzotriazole and six kinds of pyrazole were used in the concentrations shown in Table 3 below thus preparing etching solutions (the balance component being water), which were then used to etch an electrodeposited Cu foil (3 cm×5 cm) with 0.3 μm. The etching treatment was performed using a spray having a full-cone nozzle, and the temperature thereof was set to about 30° C. The surface morphologies in the etching amount of 0.3 μm were visually compared using FE-SEM images (FIGS. 4˜11).

TABLE 3

| | | | Etching | Roughness | | |
|---|---|---|---|---|---|---|
| | Benzotrizole | Pyrazole | amount | Ra | | Etching |
| | (ppm) | (ppm) | (μm) | (nm) | SD | Uniformity |
| Ex. 4 | 5MBTZ | 1HP | 0.3 | 299 | 6.6 | ⊚ |
| | (1000 ppm) | (300 ppm) | | | | |
| Ex. 5 | 5MBTZ | 4DAA | 0.3 | 309 | 5.2 | ⊚ |
| | (1000 ppm) | (500 ppm) | | | | |
| Ex. 6 | 5MBTZ | 3A5HP | 0.3 | 307 | 3.8 | ⊚ |
| | (1000 ppm) | (300 ppm) | | | | |
| Ex. 7 | 5MBTZ | 35DMP | 0.3 | 283 | 4.2 | ⊚ |
| | (1000 ppm) | (500 ppm) | | | | |
| Ex. 8 | 1HBTA | AN | 0.3 | 265 | 4.9 | ⊚ |
| | (1000 ppm) | (300 ppm) | | | | |
| Ex. 9 | 1HBTA | 4AA | 0.3 | 286 | 6.1 | ⊚ |
| | (1000 ppm) | (500 ppm) | | | | |
| Ex. 10 | 1HBTA | 4DAA | 0.3 | 318 | 8.7 | ⊚ |
| | (1000 ppm) | (300 ppm) | | | | |
| Ex. 11 | 1HBTA | 35DMP | 0.3 | 287 | 5.0 | ⊚ |
| | (1000 ppm) | (300 ppm) | | | | |

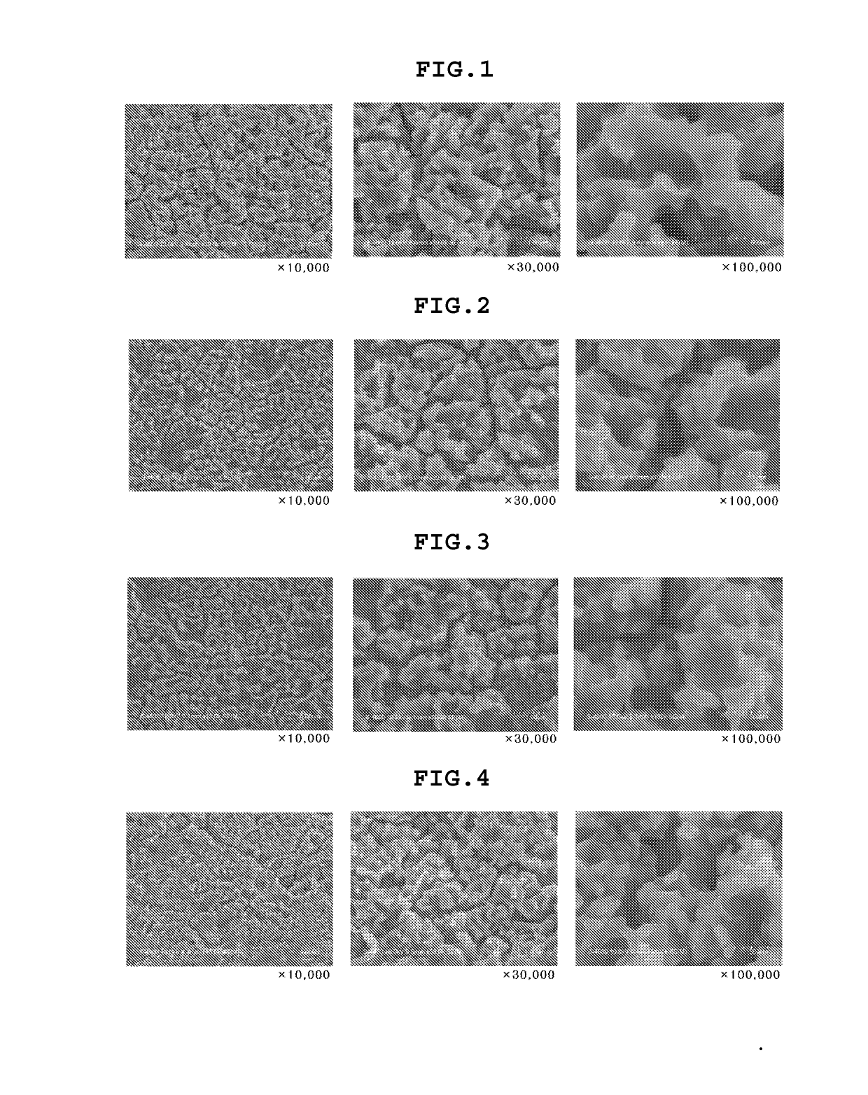

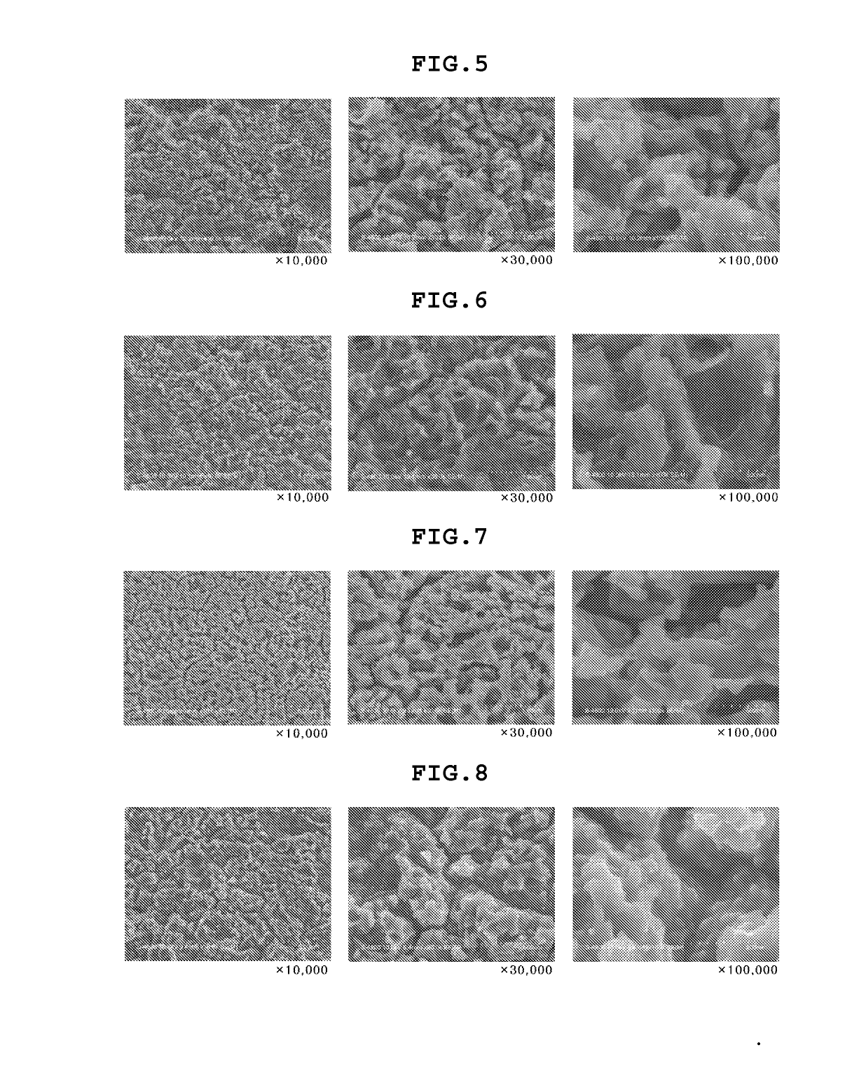

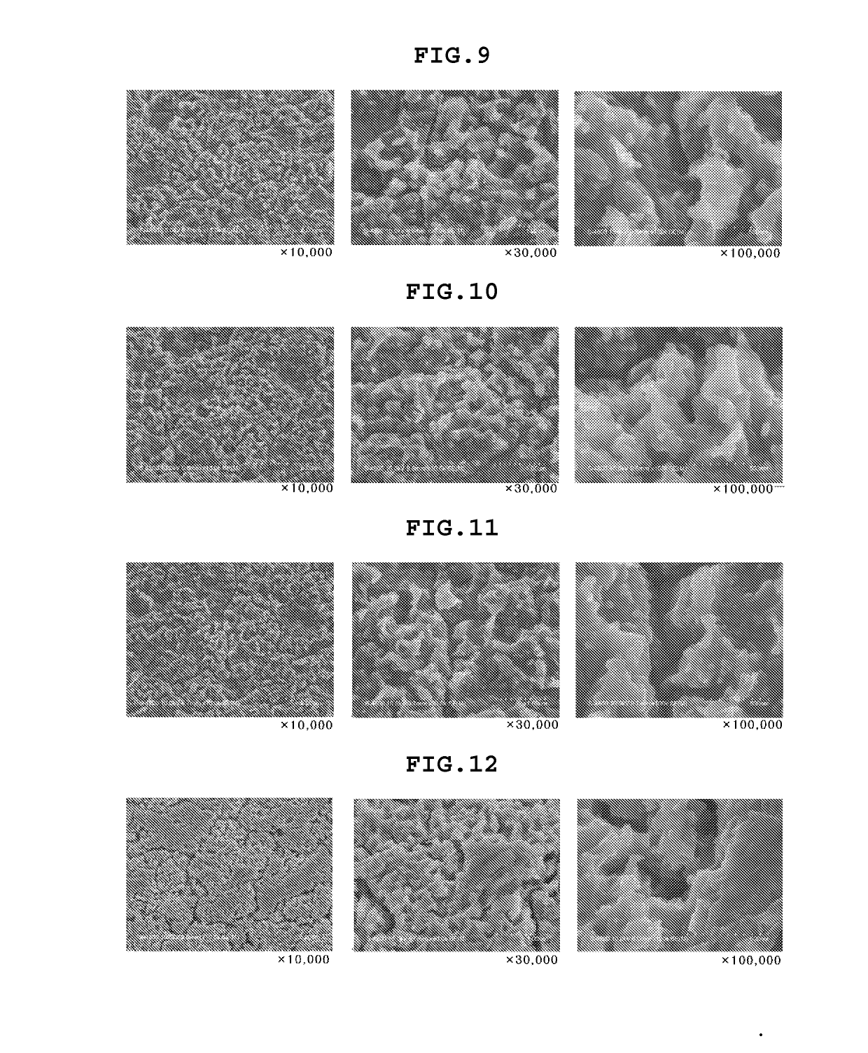

As is apparent from Tables 2 and 3, Comparative Examples 6 to 13 (FIGS. 17˜24) using different concentrations of benzotriazole and pyrazole exhibited an etching uniformity that was inferior to Examples 1 to 12, and also, the SD of surface roughness Ra of the etched Cu foil in Examples 1 to 12 was low and thus the formation of fine porous metal surface irregularities and micro anchors was observed as shown in FIGS. 1 to 12.

### Example 12

An electrodeposited Cu foil (400 mm×400 mm) was cleaned with 10% aqueous sodium hydroxide and washed with water in the first process, and then etched with about 0.3 μm using an etching solution comprising 0.6 wt % of hydrogen peroxide, 1.8 wt % of sulfuric acid, 0.9 g/l of 5-methylbenzotriazole, 0.6 g/l of 3,5-dimethylpyrazole, 0.0015 g/l of chlorine ions and a remainder of water in the second process, followed by performing cleaning with 10% aqueous sodium hydroxide, water washing, cleaning with 5% aqueous sulfuric acid, water washing, and drying. All processes of the etching treatment were performed using a spray having a full-cone nozzle, and the etching was conducted at about 30° C. whereas the other procedures were performed at room temperature. The surface of Cu after etching treatment was coated with a solder resist SR 7300 available from Hitachi, photo-exposed, developed, and cured thus forming a solder resist layer. The force of adhesion of the Cu foil was measured according to Cu peel strength measurement methods based on STM-650 or JISC6481. The results are shown in Table 4 below.

### Comparative Example 14

An electrodeposited Cu foil (400 mm×400 mm) was etched with about 0.6 μm and about 1 μm using an etching solution composed mainly of commercially available Cu formate. The surface of the etched Cu was coated with SR 7300 available from Hitachi, photo-exposed, developed, and cured thus forming a solder resist layer. The force of adhesion of the Cu foil was measured according to Cu peel strength measurement methods based on STM-650 or JISC6481. The results are shown in Table 4 below.

### Comparative Example 15

An electrodeposited Cu foil (400 mm×400 mm) was cleaned with 10% aqueous sodium hydroxide and washed with water in the first process, and then etched with about 0.3 μm using an etching solution comprising 0.6 wt % of hydrogen peroxide, 1.8 wt % of sulfuric acid, 0.6 g/l of 3,5-dimethylpyrazole, 0.0015 g/l of chlorine ions and a remainder of water in the second process, followed by performing cleaning with 10% aqueous sodium hydroxide, water washing, cleaning with 5% aqueous sulfuric acid, water washing and drying. All processes of the etching treatment were performed using a spray having a full-cone nozzle, and the etching was carried out at about 30° C. whereas the other procedures were performed at room temperature. The surface of the etched Cu was coated with SR 7300 available from Hitachi, photo-exposed, developed, and cured thus forming a solder resist layer. The force of adhesion of the Cu foil was measured according to Cu peel strength measurement methods based on STM-650 or JISC6481. The results are shown in Table 4 below.

TABLE 4

| | Etching amount | Surface Roughness Ra | Force of Adhesion |
|---|---|---|---|
| | (μm) | (μm) | (kgf/cm²) |
| Ex. 12 | 0.3 | 280 | 1.03 |
| C. Ex. 14 | 0.6 | 489 | 0.76 |
| | 1.0 | 548 | 1.01 |
| C. Ex. 15 | 0.3 | 220 | 0.37 |

As is apparent from Table 4, in Example 12 the force of adhesion of about 0.7 kgf/cm² or more could be obtained even with a small etching amount and low surface roughness, and such a force of adhesion corresponded to the force of adhesion of the substrate having a high surface roughness with the etching amount of about 1 μm in Comparative Example 14. Comparative Example 15 using one kind of azole manifested low surface roughness and almost none of the force of adhesion. Accordingly, the use of benzotriazole and pyrazole can form a roughness having anchoring effects even given a small etching amount, thus achieving the targeted force of adhesion.

As described hereinbefore, the present invention provides an etching solution and a method of manufacturing a printed wiring substrate using the same. According to the present invention, the etching solution can form porous metal surface irregularities and micro anchors even with a smaller etching amount of the metal compared to a conventional etching solution for forming a surface roughness of metal, for example Cu, with an excessive etching amount, thereby obtaining a high force of adhesion between the metal and an insulating material. Also, a small degree of compensation can be applied in the course of forming a circuit because of the small etching amount of the metal, so that the attachment portion of a photosensitive resin is enlarged thus effectively forming a fine circuit.

Although the embodiments of the present invention have been disclosed for illustrative purposes, those skilled in the art will appreciate that a variety of different modifications, additions and substitutions are possible, without departing from the scope and spirit of the invention as disclosed in the accompanying claims. Accordingly, such modifications, additions and substitutions should also be understood as falling within the scope of the present invention.

What is claimed is:

1. An etching solution comprising hydrogen peroxide, sulfuric acid, chlorine ions, benzotriazole and pyrazole.

2. The etching solution of claim 1, comprising 1˜10 g/l of hydrogen peroxide, 5˜30 g/l of sulfuric acid, 0.0001˜0.005 g/l of chlorine ions, 0.1˜1 g/l of benzotriazole and 0.1˜0.5 g/l of pyrazole.

3. The etching solution of claim 1, wherein the benzotriazole is at least one selected from among 1H-benzotriazole, 4-methylbenzotriazole and 5-methylbenzotrizole.

4. The etching solution of claim 1, wherein the pyrazole is at least one selected from among 3,5-dimethylpyrazole, 2,3-dimethyl-1-phenyl-3-pyrazolin-5-one, 4-amino-2,3-dimethyl-1-phenyl-5-pyrazolone, 4-dimethylaminoantipyrine and 3-amino-5-hydroxypyrazole.

5. The etching solution of claim 1, wherein a molar ratio of hydrogen peroxide and sulfuric acid (hydrogen peroxide/sulfuric acid) is 0.15˜1.0.

6. A method of manufacturing a printed wiring substrate, comprising forming a first metal wiring on a first insulating resin layer, and forming a second insulating resin layer on the first metal wiring; and forming a second metal wiring on the second insulating resin layer, and forming a third insulating resin layer on the second metal wiring,
wherein a surface of each of the first metal wiring and the second metal wiring is treated with an alkali solution, roughened using an etching solution comprising hydrogen peroxide, sulfuric acid, chlorine ions, benzotriazole and pyrazole, and then subjected to anti-rust treatment using an anti-rust agent.

7. The method of claim 6, wherein the etching solution comprises 1˜10 g/l of hydrogen peroxide, 5˜30 g/l of sulfuric acid, 0.0001˜0.005 g/l of chlorine ions, 0.1˜1 g/l of benzotriazole and 0.1˜0.5 g/l of pyrazole.

8. The method of claim 6, wherein the anti-rust agent is an aqueous solution containing a silane compound or an amine compound.

9. The method of claim 6, wherein an etching amount of each of the first metal wiring and the second metal wiring is 0.5 μm or less, and a surface roughness Ra thereof is 0.5 an or less.

10. The method of claim 6, wherein a surface area of each of the first metal wiring and the second metal wiring after etching is 2˜20 times a surface area of the metal wiring before etching.

11. The method of claim 6, wherein the benzotriazole is at least one selected from among 1H-benzotriazole, 4-methylbenzotriazole and 5-methylbenzotrizole.

12. The method of claim 6, wherein the pyrazole is at least one selected from among 3,5-dimethylpyrazole, 2,3-dimethyl-1-phenyl-3-pyrazolin-5-one, 4-amino-2,3-dimethyl-1-phenyl-5-pyrazolone, 4-dimethylaminoantipyrine and 3-amino-5-hydroxypyrazole.

13. The method of claim 6, wherein the alkali solution is an aqueous solution at pH of 9 or more.

14. The method of claim 6, wherein a temperature of the etching solution is 20˜40° C.
